(19) United States
(12) Patent Application Publication
(10) Pub. No.: US 2019/0267349 A1
(43) Pub. Date: Aug. 29, 2019

(54) METHOD FOR MANUFACTURING A PLURALITY OF ELECTRONIC UNITS

(71) Applicant: STMicroelectronics (Grenoble 2) SAS, Grenoble (FR)

(72) Inventors: Marie-Astrid PIN, La Murette (FR); Karine SAXOD, Les Marches (FR); Jean-Michel RIVIERE, Froges (FR)

(73) Assignee: STMicroelectronics (Grenoble 2) SAS, Grenoble (FR)

(21) Appl. No.: 16/282,594

(22) Filed: Feb. 22, 2019

(30) Foreign Application Priority Data
Feb. 27, 2018 (FR) 1851718

(51) Int. Cl. H01L 23/00; H01L 31/0203; H01L 33/48; H01L 21/78

(52) U.S. Cl. CPC H01L 24/97; H01L 24/48; H01L 31/0203; H05K 2201/10151; H01L 21/78; H01L 2224/48091; H01L 2224/48137; H01L 33/483

(57) ABSTRACT

Individual electronic units are formed by cutting a collective assembly. A collective support plate is provided which includes electronic chips. A collective cover plate is provided which includes ribs defining recesses. The collective assembly is formed by mounting the collective cover plate to the collective support plate in a manner where the electronic chips are located in the recesses and the ribs are located between electronic chips. A bead of glue is interposed between ends of the ribs and the surface of the collective support plate. After the glue is hardened, a cutting operation is performed on the collective assembly by cutting through the ribs and the collective support plate to produce the individual electronic units.

### PRIORITY CLAIM

This application claims the priority benefit of French Application for Patent No. 1851718, filed on Feb. 27, 2018, the content of which is hereby incorporated by reference in its entirety to the maximum extent allowable by law.

### TECHNICAL FIELD

The present invention concerns the area of microelectronics and, more precisely, the area of manufacturing units which include electronic chips in recesses.

### SUMMARY

According to an embodiment, a method is proposed for manufacturing a plurality of electronic devices. The method comprises the following steps: providing a collective support plate which is fitted, on an assembly face, with computer chips which are spaced from one another; providing a collective cover plate which has ribs in a face, between which ribs recesses are created; performing an operation to assemble the collective cover plate above the collective support plate, in a position such that the chips are situated in the recesses, by interposing beads of glue between the assembly face of the support plate and the ribs of the cover plate; hardening the beads of glue; and performing an operation for cutting the support plate and the cover plate, through the ribs, so as to obtain a plurality of electronic devices each comprising a portion of the support plate, provided with at least one chip, and a portion of the cover plate, forming a cover encapsulating said chip in the corresponding recess, including a front wall which is situated above the chip and a peripheral wall which includes a portion of ribs adjacent to said recess.

Such collective manufacturing improves the desired positioning and simplifies the manufacture of electronic units.

The cutting operation can include the realization of saw cuts which traverse the collective support plate and the collective cover plate simultaneously.

The cutting operation can include, in a separate manner, the realization of saw cuts which traverse the collective support plate and the realization of saw cuts which traverse the collective cover plate.

The saw cuts which traverse the collective support plate can be broader than the saw cuts which traverse the collective cover plate such that the flanks of the portion of the collective cover plate extend beyond the flanks of the portion of the collective support plate.

The collective support plate and the collective cover plate can each be placed in position with respect to one another using positioning means.

The positioning means can include positioning pins which cooperate with transfer supports which carry the collective support plate and the collective cover plate respectively and/or with the collective support plate and the collective cover plate.

The positioning means can include optical positioning means.

The collective cover plate can have through-passages which open out into the recesses.

The collective cover plate can be provided with optical elements which allow the light to pass through, facing said through-passages.

The chips can include light sensors and/or light emitters.

### BRIEF DESCRIPTION OF THE DRAWINGS

Electronic units and methods for manufacturing electronic units are now going to be described by way of exemplary embodiments, which are shown by the drawing, in which:

FIG. 1 shows a section of a collective device;

FIG. 2 shows a view from above of the collective device in FIG. 1;

FIG. 3 shows a section of another collective device;

FIG. 4 shows a view from above of the collective device in FIG. 3;

FIG. 5 shows a section of an assembly produced which includes the collective devices in FIGS. 1 and 3;

FIG. 6 shows in section a method for producing electronic units;

FIG. 7 shows a section of a single electronic unit resulting from the production method in FIG. 6;

FIG. 8 shows in section another method of producing electronic units; and

FIG. 9 shows a section of a single electronic unit resulting from the production method in FIG. 8.

### DETAILED DESCRIPTION

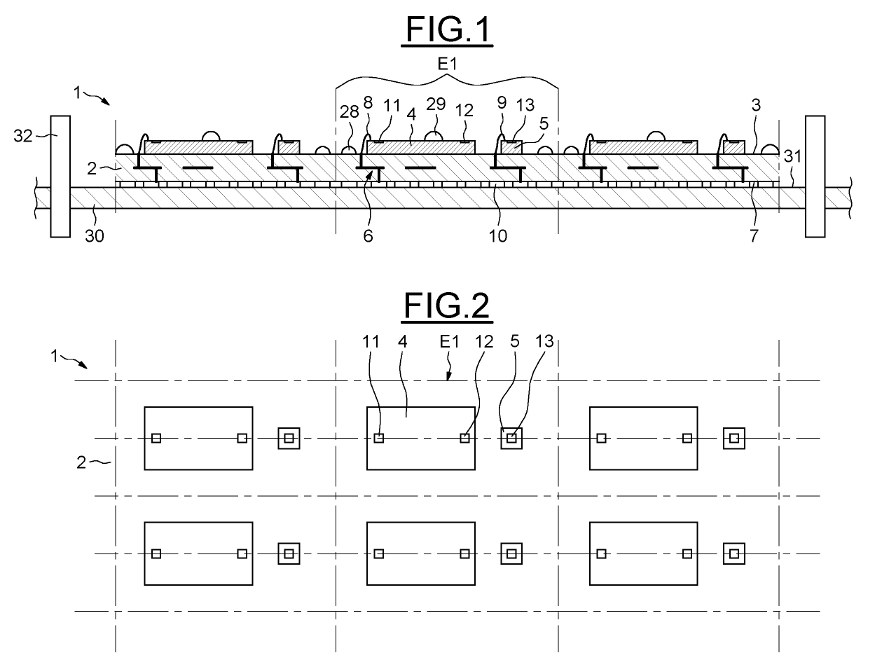

FIGS. 1 and 2 show a collective device 1 which includes a collective support plate 2 which is fitted, on a front assembly face 3, with a plurality of electronic chips, which are, for example, glued, spaced apart from one another and situated on rectangular slots E1, which form a mosaic and are adjacent longitudinally and transversally, of the front assembly face 3 and are spaced from the adjacent edges of said slots.

In particular, the collective support plate 2 is provided with a plurality of pairs of electronic chips 4 and 5 which are situated respectively in the slots E1.

The collective support plate 2 is produced from a dielectric material which is opaque and is provided with a plurality of integrated electric connection networks 6, which are provided respectively in the slots E1 and are configured to realize electric connections between the front assembly face 3 and the rear face 7 of the collective support plate 2.

The chips 4 and 5 are connected respectively to the electric connection networks 6 by electricity-conducting wires 8 and 9, between front pads of the chips 4 and 5 and pads of the front face 3, and the rear face 7 is provided with exterior electric connection pads 10 which are connected to the electric connection networks 6. The wires 8 and/or 9 could be replaced by beads between the chips 4 and/or 5 and the electric connection networks 6.

The chips 4 and 5 are arranged in the manner of one slot E1 to another, for example along longitudinal lines.

The chips 4 are fitted respectively with light sensors 11 and 12 which are spaced apart longitudinally and the chips 5 are fitted with light emitters 13.

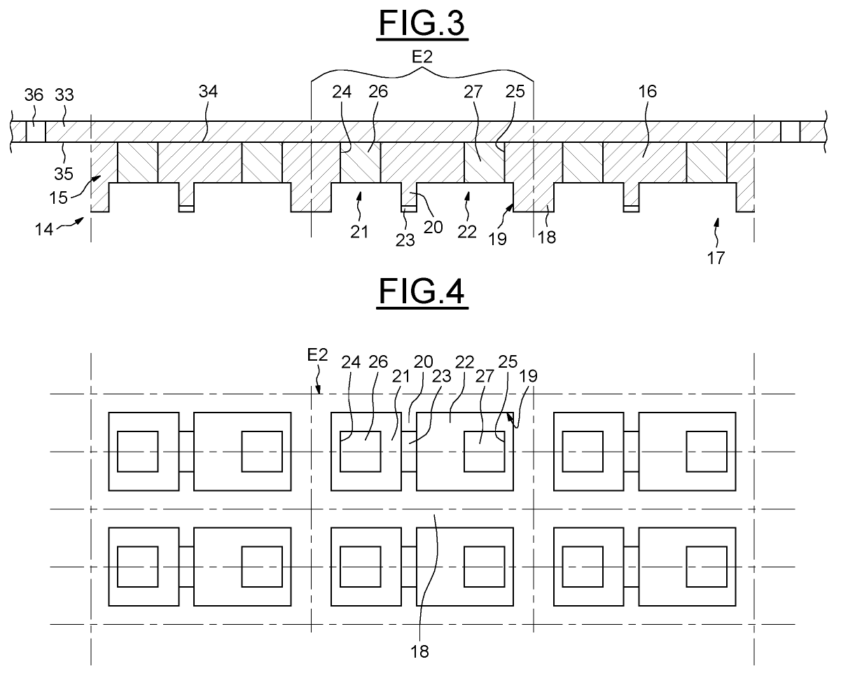

FIGS. 3 and 4 also show a collective device 14 which includes a collective cover plate 15, which is produced in a dielectric material, and includes a front wall 16 and has, on a rear assembly face 17, main ribs 18 which jut out with respect to the front wall 16, extend longitudinally and transversely and between them form recesses 19.

The recesses 19 are situated on the adjacent rectangular slots E2, which form a mosaic, of the collective cover plate 12 such that the adjacent edges of said slots E2 move through the main ribs 15.

The collective cover plate 14 also has secondary ribs 20 which extend into the recesses 19, transversely between corresponding opposite longitudinal ribs 18 such that each recess 19 is divided into two chambers 21 and 22. The secondary ribs 20 have indentations 23 in their end edges.

The collective cover plate 14 is produced in an opaque material and can be obtained by molding.

In each slot E2, the front wall 16 of the collective cover plate 14 has through-passages 24 and 25, which are situated facing chambers 21 and 22 respectively, and which are fitted with optical elements 26 and 27 that allow the light to pass through, corresponding to the through-passages 24 and 25.

According to an embodiment variant, shown in the drawing, the optical elements 26 and 27 are inserted into the front wall 16 by over-molding. According to another embodiment variant (not shown), the optical elements can be applied and fixed by gluing in the through-passages 24 and 25 or on one side or the other of the front wall 16.

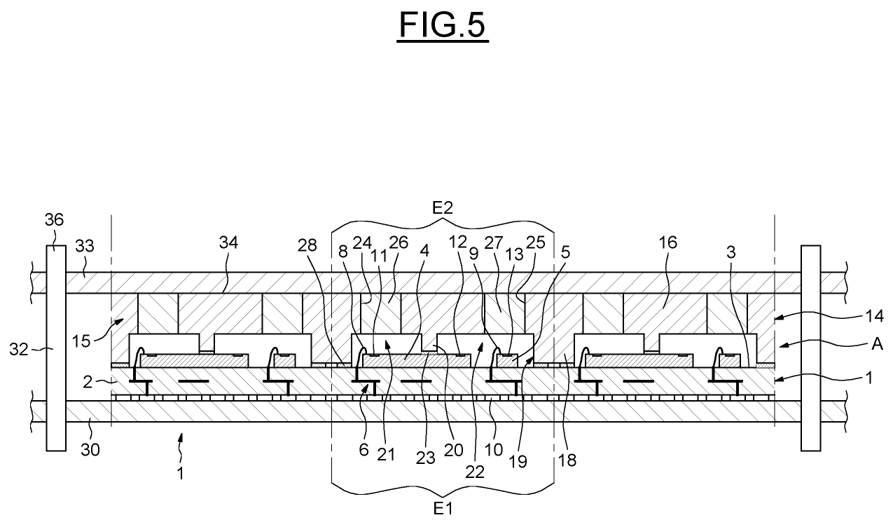

As shown in FIG. 5, the collective devices 1 and 14 are intended to be assembled one above the other in the following manner, with the assistance of appropriate tools.

In order to perform the assembly operation, the collective support plate 2 and the collective cover plate 15 are placed one above the other, in a position such that the assembly face 3 of the collective support plate 2 and the assembly face 17 of the collective cover plate 14 face one another and the slots E1 and E2 face one another and coincide.

The collective devices 1 and 14 are then moved closer to one another such that the pairs of chips 4 and 5 are situated respectively in the recesses 19, the secondary ribs 20 straddle the chips 4 and traverse the indentations 23, the sensors 11 and 12 of the chips 4 are in the chambers 21 and 22 respectively and the chips 5 are in the chambers 22. Collective positioning of collective devices 1 and 14 is thus realized.

As shown in FIG. 1, prior to realizing the assembly operation, beads of glue 28 are arranged along the edges of slots E1 and beads of glue 29 are arranged on the chips 4, between and at a spacing from sensors 11 and 12, and on the assembly face 3, on both sides of the chips 4.

As shown in FIG. 5, during the assembly operation, the beads of glue 28 are squashed and interposed between the assembly face 3 of the collective support plate 2 and the ends of the main ribs 18 of the collective cover plate 15 and the beads of glue 29 are squashed and interposed between the chips 4 and the indentations 23 of the secondary ribs 20 of the collective cover plate 15 and between the assembly face 3 of the collective support plate 2 and the ends of the secondary ribs 20 of the collective cover plate 15.

The beads of glue 28 and 29 are then hardened, for example in a furnace so as to fix the collective devices 1 and 14 between them, the beads of glue 28 and 29 obtained being in an opaque material. A collective assembly A is then produced.

The assembly tools can be fitted with positioning means for each of the collective devices 1 and 14 so as to position the slots E1 and E2 one above the other in a precise manner so that they coincide with one another.

As shown in FIG. 1, the collective device 1 can be carried by a transfer support 30 in a position such that the rear face 7 is supported by a face 31 of the transfer support 30. The transfer support 30 can be provided with positioning pins 32 which extend perpendicularly to its face 31.

According to an embodiment variant, at least certain of the pins 32 can be situated on the periphery of and spaced apart from the collective support plate 2. According to another embodiment variant, at least certain of the pins 32 can traverse positioning through-passages of the collective support plate 2, arranged outside the zone provided for slots E1.

As shown in FIG. 3, the collective device 14 can be carried by a transfer support 33 in a position such that the front face 34 of the cover plate 15, opposite its assembly face 17, is supported by a face 35 of the transfer support 33. The transfer support 33 can be provided with positioning holes 36.

According to an embodiment variant, at least certain of the holes 36 can be situated on the periphery of and spaced apart from the collective cover plate 15. According to another embodiment variant, at least certain of the holes 36 can face the collective cover plate 15 and the collective cover plate can be provided with positioning through-holes which coincide with the holes 36 and are arranged outside the zone provided for the slots E2.

As shown in FIG. 5, during the assembly operation described above, the positioning pins 32 of the transfer support 30 are engaged in the positioning holes 36 of the transfer support 33.

According to an embodiment variant, as an alternative to the positioning pins 32, the transfer supports 30 and 33 could be provided with optical positioning means.

Once the assembly A is obtained and one of the transfer supports 30 and 33 has been removed, a cutting operation is then performed along the longitudinal and transverse edges of the slots E1 and E2 in coincidence with and perpendicularly to the collective plates 2 and 16.

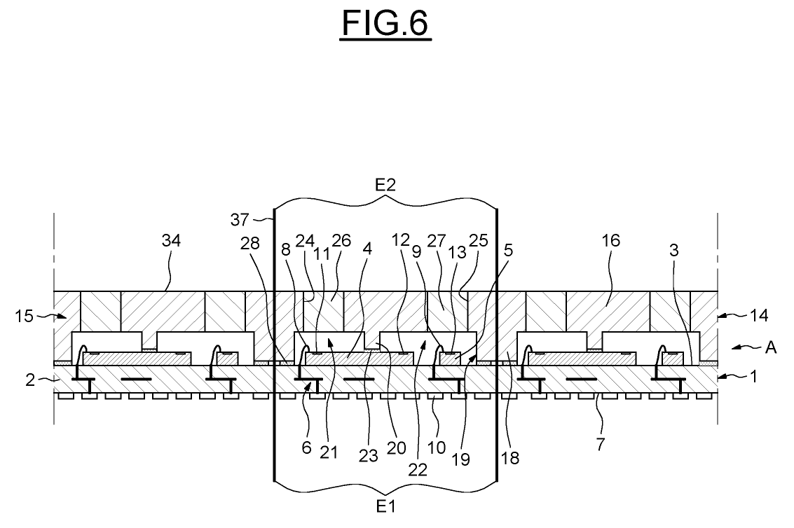

According to an embodiment variant shown in FIG. 6, the cutting operation includes the realization of saw cuts 37 which simultaneously traverse the collective support plate 2 and the collective cover plate 15, moving through the main ribs 18.

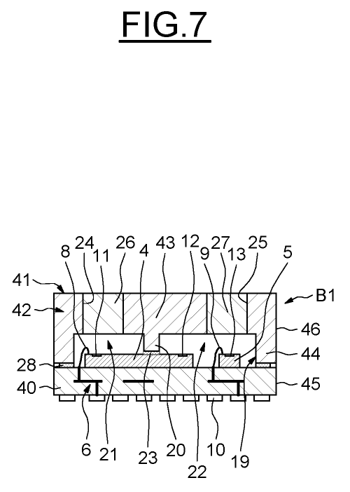

As shown in FIG. 7, a plurality of electronic units B1 is produced which each include a portion of the collective support plate, forming a support plate 40, and a portion of the cover plate, forming an encapsulating cover 41 which delimits a corresponding recess 19.

The support plate 40 is provided with a network of integrated electric connections 6 and is fitted with a chip 4 and a chip 5.

The encapsulating cover 41 includes a body 42 which includes a front wall 43, a peripheral wall 44 which includes a portion of the main ribs 18 adjacent to the corresponding recess 19 and a secondary wall 20 which forms a partition wall between the chambers 21 and 22. The front wall 42 is situated above and at a spacing from the chips 4 and 5 and the wires 8 and 9 and is provided with corresponding optical elements 26 and 27, above the sensor 11 and above the emitter 13 respectively. The peripheral wall 43 is situated on the periphery of and spaced apart from the chips 4 and 5 and the wires 8 and 9.

The peripheral flanks 45 and 46 of the support plate 40 and of the encapsulating cover 41, produced by the cut, are in alignment.

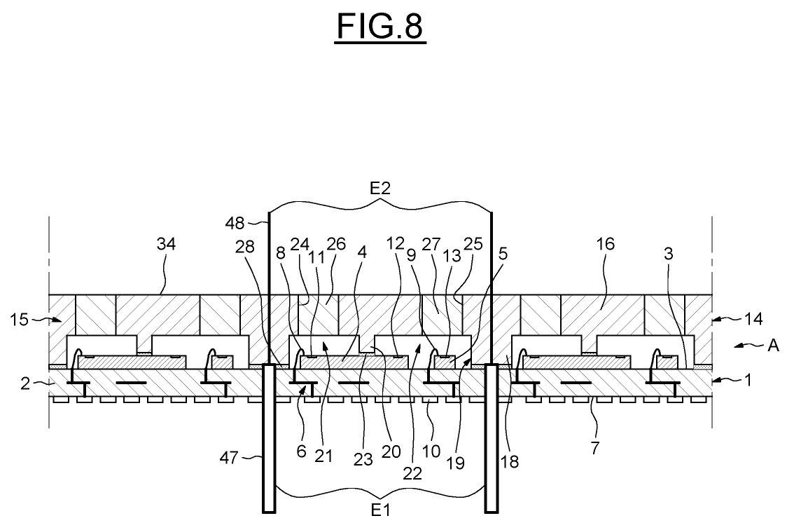

According to another embodiment variant, the cutting operation includes, in a separate manner, a cut of the collective support plate 2 and a cut of the collective cover plate 15, along the longitudinal and transverse edges of the slots E1 and E2. For example, as shown in FIG. 8, the cutting operation includes, in a separate manner, on the one hand, the realization of saw cuts 47 from the rear face 7 and traversing the collective support plate 2 and, on the other hand, the realization of saw cuts 48 from the face 34 of the collective cover plate 15 and traversing said collective cover plate 15, moving through the main ribs 18.

The saw cuts 47 and 48 can be of the same width. Electronic units equivalent to the electronic units B1 in FIG. 8 are therefore produced.

Nevertheless, as shown specifically in FIG. 8, the saw cuts 48 can be broader than the saw cuts 47.

In this case, having kept the transfer support 33, it is advantageous for the cutting operation to include the realization of saw cuts 47 from the rear face 7 and traversing the collective support plate 2 then the realization of less broad saw cuts 48 through the collective cover plate 15, from the same rear face 7 of the support plate 2 and passing through the saw cuts 47 which have already been realized.

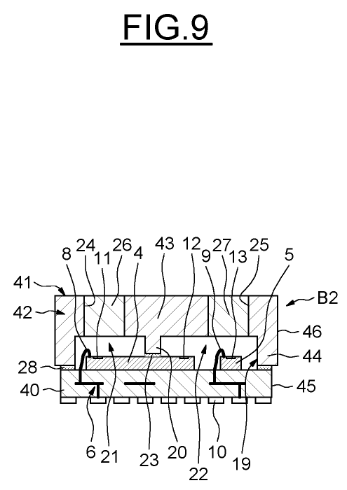

As shown in FIG. 9, a plurality of electronic units B2 is therefore obtained which differ from the electronic units B1 in that in each electronic device B2, the encapsulating cover 41, at its periphery, compared to the peripheral edge of the support plate 44, extends beyond the flanks 45 being set back compared to the flanks 46.

Each electronic unit produced B1 and B2 is able to operate in the following manner.

The emitter 13 of the chip 5 emits light radiation, for example infrared, to the outside through the optical element 27. Said light radiation which is present in the recess 19 is sensed by the sensor 12 of the chip 4. The sensor 11 of the chip 4 senses the outside light radiation through the optical element 26 which can be an infrared filter which is able to form an optical lens for focusing the light toward the sensor 11. Each electronic device B1 and B2 can constitute a means for detecting the proximity of a body by processing the signals emitted by the sensors 11 and 12.

According to an embodiment variant, the collective devices 1 and 14 could be adapted such that the single electronic units produced include at least one electronic chip respectively which is situated in its entirety in a recess of the encapsulating cover or include electronic chips respectively which are situated in their entirety respectively in multiple recesses of the encapsulating covers produced.

1. A method for manufacturing a plurality of electronic devices, said method comprising the steps of:
providing a collective support plate including, on an assembly face, electronic chips that are spaced from one another;
providing a collective cover plate including, on a face, ribs which define recesses;
performing an operation to assemble the collective cover plate above the collective support plate, in a position such that the electronic chips are situated in the recesses, by interposing beads of glue between the assembly face of the collective support plate and the ribs of the collective cover plate;
hardening the beads of glue; and
cutting the collective support plate and the collective cover plate, through the ribs, so as to obtain a plurality of electronic devices each comprising a portion of the collective support plate, provided with at least one electronic chip, and a portion of the collective cover plate, forming a cover which encapsulates said electronic chip in the corresponding recess, including a front wall which is situated above the electronic chip and a peripheral wall which includes a portion of ribs adjacent to said recess;
wherein cutting comprises separately making one saw cut which traverses the collective support plate and another saw cut which traverses the collective cover plate.

2. The method according to claim 1, wherein said one saw cut which traverses the collective support plate is made from a face of the collective support plate and said another saw cut which traverses the collective cover plate is made from a face of the collective cover plate.

3. The method according to claim 2, wherein said one saw cut which traverses the collective support plate is made before said another saw cut which traverses the collective cover plate.

4. The method according to claim 2, wherein said one saw cut which traverses the collective support plate is wider than said another saw cut which traverses the collective cover plate.

5. The method according to claim 1, further comprising aligning the collective support plate and the collective cover plate relative to each other using positioning means.

6. The method according to claim 5, wherein the positioning means include positioning pins which cooperate with transfer supports carrying the collective support plate and the collective cover plate, respectively.

7. The method according to claim 5, wherein the positioning means include positioning pins which cooperate with the collective support plate and the collective cover plate.

8. The method according to claim 5, wherein the positioning means include optical positioning means.

9. The method according to claim 1, wherein the collective cover plate has through-passages which open out into the recesses.

10. The method according to claim 9, wherein said through-passages include optical elements which allow the light to pass through.

11. The method according to claim 1, wherein the electronic chips include at least one of light sensors and light emitters.

12. A method for manufacturing a plurality of electronic devices, said method comprising the steps of:
aligning a collective cover plate that includes ribs which define recesses to a collective support plate that includes electronic chips such that the electronic chips are positioned within the recesses and the ribs are positioned between the electronic chips;
interposing beads of glue between ends of the ribs and a surface of the collective support plate;
hardening the beads of glue to attach the collective cover plate to the collective support plate and form a collective assembly; and
cutting the collective assembly through a middle portion of the ribs of the collective cover plate and through the collective support plate so as to separate the collective assembly in a plurality of electronic devices, wherein each electronic device includes a portion of the collective support plate, at least one electronic chip, and a portion of the collective cover plate;
wherein cutting comprises separately making one saw cut which traverses the collective support plate and another saw cut which traverses the collective cover plate.

13. The method according to claim 12, wherein said one saw cut which traverses the collective support plate is made from a face of the collective support plate and said another saw cut which traverses the collective cover plate is made from a face of the collective cover plate.

14. The method according to claim 13, wherein said one saw cut which traverses the collective support plate is made before said another saw cut which traverses the collective cover plate.

15. The method according to claim 13, wherein said one saw cut which traverses the collective support plate is wider than said another saw cut which traverses the collective cover plate.

16. The method according to claim 12, wherein aligning comprises using a physical positioning means.

17. The method according to claim 16, wherein the physical positioning means comprises alignment positioning pins.

18. The method according to claim 12, wherein aligning comprises using optical positioning means.
